(19) United States
(12) Patent Application Publication
(10) Pub. No.: US 2026/0121618 A1
(43) Pub. Date: Apr. 30, 2026

(54) MULTILAYER PIEZOELECTRIC SUBSTRATE DEVICE WITH MODIFIED INTERDIGITAL TRANSDUCER STRUCTURE TO IMPROVE INSERTION LOSS

(71) Applicant: SKYWORKS SOLUTIONS, INC., Irvine, CA (US)

(72) Inventors: Rei Goto, Osaka-Shi (JP); Yuya Hiramatsu, Neyagawa-Shi (JP)

(21) Appl. No.: 19/366,968

(22) Filed: Oct. 23, 2025

Related U.S. Application Data
(60) Provisional application No. 63/714,213, filed on Oct. 31, 2024.

(51) Int. Cl. H03H 9/64; H03H 9/02; H03H 9/145

(52) U.S. Cl. CPC H03H 9/6483; H03H 9/02818; H03H 9/145

(57) ABSTRACT

An acoustic wave device, a radio frequency ladder filter, and an electronics module are provided. The acoustic wave device comprises a layer of carrier substrate, a layer of dielectric material, a layer of piezoelectric material, a pair of interdigital transducer electrodes each including a bus bar and a plurality of electrode fingers extending from the bus bar to the distal ends of the electrode fingers at an edge region of the interdigital transducer electrode, and trench portions located in the upper surface of the layer of piezoelectric material, said trench portions being overlapped by the edge regions of the interdigital transducer electrodes, the electrode fingers having a region at their distal end that has a reduced width, the reduced width region having a length of between about 1.1λ and 1.2λ, where λ is the wavelength of the acoustic wave to be generated.

### CROSS-REFERENCE TO RELATED APPLICATIONS

This application claims priority under 35 U.S.C. § 119(e) to U.S. Provisional Patent Application Ser. No. 63/714,213, titled “MULTILAYER PIEZOELECTRIC SUBSTRATE DEVICE WITH MODIFIED INTERDIGITAL TRANSDUCER STRUCTURE TO IMPROVE INSERTION LOSS,” filed Oct. 31, 2024, the entire content of which is incorporated herein by reference for all purposes.

### BACKGROUND

### Field of Technology

Aspects and embodiments disclosed herein relate to an acoustic wave device, a radio frequency ladder filter, and an electronics module comprising at least one radio frequency filter including the same. In particular, aspects and embodiments disclosed herein relate to an acoustic wave device including trench portions in a layer of piezoelectric material and electrode fingers having regions at their distal ends that have a reduced width for transverse mode suppression.

### Description of the Related Technology

Multilayer piezoelectric substrates (MPSs) are often used in acoustic wave devices, such as surface acoustic wave (SAW) devices. Several structures for suppressing unwanted transverse modes in such devices are known. However, the various known structures each have different drawbacks.

FIGS. 1A and 1B show one type of acoustic wave device 100. FIG. 1A is a cross-section through the line marked A on the plan view of FIG. 1B. The acoustic wave device 100 has a multilayer piezoelectric substrate (MPS) including a carrier substrate 102, a layer of dielectric material 104 disposed on an upper surface of the carrier substrate 102, and a layer of piezoelectric material 106 disposed on the layer of dielectric material 104. An interdigital transducer (IDT) 108 is disposed on top of the layer of piezoelectric material 106. In the acoustic wave device 100 of FIGS. 1A and 1B, the electrode fingers in the IDT 108 include hammer head portions 110 to suppress transverse modes. The hammer head portions 110 are sections of the electrode fingers in edge regions E of the IDT that have a width (in a direction perpendicular to the lengthwise extension of the electrode fingers) larger than the width of each finger in a central region C of the IDT 108. In other words, a duty factor (DF) of the IDT 108 is greater in the edge regions E of the IDT compared to the duty factor of the IDT in the central region C of the IDT.

An illustrative diagram showing what is meant by the term “duty factor” is provided in FIG. 6. In general, the width of the IDT fingers (w) compared to the width of the spacing between the same part of the IDT fingers (p) sets the duty factor (DF). Specifically, the duty factor is defined as the fraction of the IDT width spanned by the width of the IDT fingers (in the direction of propagation of the main surface acoustic wave to be generated). Increasing the width of the IDT fingers, whilst maintaining the position of the center of each IDT finger, increases the duty factor. The DF can be expressed as:

$$DF = \frac{w}{p}$$

The hammer head portions 110 of the device of FIGS. 1A and 1B reduce the acoustic velocity in the edge regions E compared to the central region C. This velocity reduction creates a piston mode acoustic wave distribution to reduce transverse modes. To obtain a large enough velocity difference for transverse mode suppression through a larger DF in the edge regions E, the DF of the central region C of the IDT should be less than 0.5. This is because the velocity of the main acoustic mode changes rapidly with DF when the DF is less than 0.5, compared to when DF is greater than 0.5 and the velocity of the main acoustic mode does not vary with DF as much. The use of a DF narrower than 0.5 in the central region C leads to a decrease in the static capacitance. A smaller static capacitance leads to a larger size device for a given impedance, as static capacitance sets the limit on the IDT size. Therefore, the hammer head structure of FIGS. 1A and 1B can lead to an undesirable increase in size of the acoustic wave device 100.

FIG. 2A is a plan view of a surface acoustic wave (SAW) device. As shown in FIGS. 2C and 2E, the SAW device includes a includes a trench region 210. FIGS. 2B and 2C show cross-sections through the lines in FIG. 2A labeled A and B respectively. FIGS. 2D and 2E show partial cross sections through the lines in FIG. 2A labeled X and Y respectively (with only two IDT fingers shown in FIGS. 2D and 2E for clarity).

The acoustic wave device 200 includes a carrier substrate 202, a layer of dielectric material 204 disposed on an upper surface of the carrier substrate 202, and a layer of piezoelectric material 206 disposed above the layer of dielectric material 204 on the upper surface of the carrier substrate 202. Together, the carrier substrate 202, layer of dielectric material 204, and layer of piezoelectric material 206 may be referred to as a multilayer piezoelectric substrate (MPS). As can be seen in FIG. 2A, the IDT fingers of the acoustic wave device 200 have uniform widths along their lengths.

The acoustic wave device 200 further includes trench structures in the layer of piezoelectric material 206 for suppressing transverse modes. The trench portions 210 are located in the upper surface of the layer of piezoelectric material 206. The trench portions 210 overlap with the edge regions E of the IDT electrode layers 208a and 208b. In other words, the trench portions 210 are located within the active region of the IDT 208, in the edge regions E of the IDT 208, and form a boundary of the active region running parallel with the bus bars. The trench portions 210 slow down the acoustic velocity at edge of the active region to create a piston mode acoustic wave distribution, and thus suppress the transverse modes.

FIGS. 3A to 3C are simulation graphs showing a comparison between admittance curves (complex FIG. 3A, and real FIG. 3B) and quality factor curves (Q-factor, FIG. 3C) of an acoustic wave device as disclosed herein with trench portions and a comparative example without trench portions. In particular, the graphs of FIGS. 3A to 3C include a solid line trace showing the simulation results for the acoustic wave device 200 of FIGS. 2A to 2E with a length l_{Trench} of the trench portions 210 equal to 1λ and a trench depth H_LTtr of 0.007λ, where λ is the wavelength of the main acoustic wave to be generated by the IDT 208. The dashed line trace is for the comparative example, which is an acoustic wave device that does not include the trench portions.

As can be seen from the graphs of FIGS. 3A and 3B, many transverse modes are present in the dashed line trace of the comparative example. In the solid line trace for the acoustic wave device 200 with trench portions 210, on the other hand, the transverse modes are greatly suppressed.

It can therefore be seen from the previous diagrams and graphs that the inclusion of trench structures in an acoustic wave device can beneficially lead to a reduction in unwanted transverse modes. However, the inclusion of trench structures can cause problems during fabrication of the acoustic wave device. Typically these trench structures are engraved in the layer of piezoelectric material using an etching process. This typically involves an etching mask being placed to cover all of the upper surface of the layer of piezoelectric material 206 except for the edge regions E where the trench portions 210 are to be formed. Once the etching mask is in position, the trenches are etched into the layer of piezoelectric material. Various types of etching processes may be used, for example, any of chemical etching, laser etching, dry etching, vapor phase etching, wet etching, or plasma etching. The etching process is controlled to set the depth H_LTtr of the trench portions 210 cut into the layer of piezoelectric material 206, with the size and shape of the etching mask determining the width of the trench portions 210 cut into the layer of piezoelectric material 206.

FIGS. 4A to 4E show an alternative acoustic wave device 400. The acoustic wave device 400 includes a carrier substrate 402, a layer of dielectric material 404, a layer of piezoelectric material 406, an IDT 408 with an upper layer 408a and a lower layer 408b, and trench portions 410 located in the upper surface of the layer of piezoelectric material. The acoustic wave device 400 includes narrow tip portions 414 in the IDT fingers. The narrow tip portions 414 in conjunction with the trench portions 410 suppress the transverse modes.

In more detail, the narrow tip portions 414 are sections of each of the plurality of electrode fingers in the IDT 408 that have a width in a direction perpendicular to the extension direction of the electrode fingers that is smaller in the edge regions E of the IDT electrodes than in the central regions C of the IDT electrodes. The narrow tip portions 414 are located in the edge region E of each IDT electrode, and typically have a length of 1.0λ. In other words, the distal ends of the plurality of electrode fingers in each IDT electrode (the ends furthest from the respective bus bar) have a reduced width, W_{DISTAL}. The narrow tip portions 414 are also located at the sections of each IDT electrode that overlap with the edge region E of the other IDT electrode. The widths of the plurality of electrode fingers of each IDT electrode are therefore smaller in both the edge region E of that IDT electrode and the edge region E of the other IDT electrode, as best seen in the view of FIG. 4A.

Put another way, a duty factor (DF) of the pair of IDT electrodes 408 in the edge regions E is less than a duty factor of the pair of interdigital transducer electrodes in the central region C, best seen in the comparison of FIGS. 4D and 4E. As can be seen from FIG. 4E, the trench portions 410 that are cut out of the layer of piezoelectric material 406 extend a greater distance in the direction of propagation of the acoustic wave to be generated by the IDT 408, due to the larger separation between the electrode fingers in the edge regions E. As in the previous devices, the trench portions 410 do not extend underneath the sections of the plurality of electrode fingers in the edge region E (the narrow tip portions 414).

FIGS. 5A-5C are simulation graphs showing a comparison between admittance curves (complex FIG. 5A, and real FIG. 5B) and quality factor curves (Q-factor, FIG. 5C) of the acoustic wave device 400 of FIGS. 4A-4E, compared to the acoustic wave device 200 of FIGS. 2A-2E.

The dashed line trace in FIGS. 5A-5C shows the simulation for the acoustic wave device 200 of FIGS. 2A-2E, including the mini bus bars 212, and with trench portions 210 of width=1λ and depth H_LTtr=0.007λ. The solid line trace in FIGS. 5A-5C shows the simulation for the acoustic wave device 400 of FIGS. 4A-4E, without any mini bus bars, but instead with the narrow tip portions 414 with DF=0.4 in the edge regions E and DF=0.5 in the central region C, and with trench portions 410 of width=1λ and depth H_LTtr=0.015λ.

As can be seen from FIGS. 5A-5C, the suppression of the transverse modes is very comparable between the acoustic wave device 400 with narrow tip portions 414, and the acoustic wave device 200 of FIGS. 2A-2E, despite the lack of mini bus bars in the acoustic wave device 400 of FIGS. 4A-4E.

The acoustic wave device 400 of FIGS. 4A-4E therefore performs comparably to the acoustic wave device 200 of FIGS. 2A-2E when the depth H_LTtr of the trench portions 410 is larger than that of the trench portions 210. Here a trench depth of H_LTtr=0.015λ combined with the narrow tip portions 414 is comparable to a trench depth of H_LTtr=0.007λ without the narrow tip portions.

FIGS. 7A and 7B show the transmission characteristics of a filter and admittance curves of a resonator. As shown in both diagrams, the presence of unwanted transverse modes/transverse leakage show up in the form of “spikes.” In creating a SAW device for use in a filter or resonator, an important consideration is the behavior of the device around the resonant frequency. Ideally, it would be preferable to have a smooth transition in amplitude as frequency changes for the device to be more precisely controlled. Rapid changes or spikes in amplitude at different frequencies are typically undesirable, as this can make it more difficult for a user to precisely control the amplitude/frequency response. The spikes caused by these transverse modes can also degrade the performance of SAW devices and are therefore undesirable. It is therefore beneficial for the effects of such transverse modes on SAW devices to be reduced or removed entirely.

From the discussion regarding FIGS. 2A-2E, 4A-4E, and 5A-5C above, it is known that the advantages of a device with trenches can be approximately matched when trench depth is increased and narrow tip portions are included (i.e., to decrease the duty factor). This allows for a reduction in device weight whilst maintaining suppression of transverse modes. There is therefore a desire to see whether further improvements can be made to further reduce the weight of acoustic wave devices, whilst maintaining or improving the reduction in transverse mode spikes.

### SUMMARY

According to one embodiment there is provided an acoustic wave device. The acoustic wave device comprises a layer of carrier substrate, a layer of dielectric material, the layer of dielectric material having a lower surface disposed against an upper surface of the layer of carrier substrate, a layer of piezoelectric material, the layer of piezoelectric material having a lower surface disposed against an upper surface of the layer of dielectric material, a pair of interdigital transducer electrodes disposed on an upper surface of the layer of piezoelectric material, each interdigital transducer electrode including a bus bar, and a plurality of electrode fingers extending from the bus bar to distal ends of the electrode fingers at an edge region of the interdigital transducer electrode, and trench portions located in the upper surface of the layer of piezoelectric material, said trench portions being overlapped by the edge regions of the interdigital transducer electrodes, the electrode fingers having regions at their distal ends that have a reduced width, the reduced width regions having lengths of between about 1.1λ and 1.2λ, where λ is the wavelength of the acoustic wave to be generated.

In one example, the trench portions are located in areas of the upper surface of the layer of piezoelectric material that are overlapped by the edge regions of the interdigital transducer electrodes and are not covered by material of the interdigital transducer electrodes.

In one example, the trench portions extend discontinuously in a direction of propagation of an acoustic wave to be generated by the pair of interdigital transducer electrodes.

In one example, the distal end of each of the electrode fingers has a length in a direction perpendicular to a direction of propagation of an acoustic wave to be generated by the pair of interdigital transducer electrodes of 1.2λ.

In one example, the trench portions each have a width of between about 0.8λ and 1.2λ.

In one example, a duty factor at a central region of the electrode fingers is about 0.5.

In one example, the trench portions each have a depth relative to the upper surface of the layer of piezoelectric material of between about 0.004λ and 0.02λ.

In one example, the trench portions each have a depth relative to the upper surface of the layer of piezoelectric material of between about 20 nm and 30 nm.

In one example, the trench portions each have a depth relative to the upper surface of the layer of piezoelectric material of 25 nm.

In one example, the portion of the interdigital transducer electrode with reduced width is contiguous with one or more adjacent trench portions in the layer of piezoelectric material and has a same length as the length of the one or more trench portions.

In one example, the bus bars of the pair of interdigital transducer electrodes are opposing and the plurality of electrode fingers of each interdigital transducer electrode extend towards the bus bar of the other interdigital transducer electrode.

In one example, the electrode fingers of each interdigital transducer electrode interleave with one another in an active region of the pair of interdigital transducer electrodes, and form gap regions between the ends of the fingers of one of the interdigital transducer electrodes and the bus bar of the other interdigital transducer electrode.

In one example, the edge regions of the pair of interdigital transducer electrodes are located within the active region and on opposing sides of the active region.

In one example, the active region includes a central region and the edge regions of the interdigital transducer electrodes, each edge region extending from the distal ends of the plurality of electrode fingers of one of the interdigital transducer electrodes towards a center of the central region.

In one example, a duty factor of the pair of interdigital transducer electrodes in the edge regions of the interdigital transducer electrodes is less than a duty factor of the pair of interdigital transducer electrodes in the central region of the active region.

In one example, the duty factor at the distal ends of the electrode fingers is about 0.4, and the duty factor at remainders of the electrode fingers is about 0.5.

In one example, the duty factor at the distal ends of the electrode fingers is between about 0.56 and 0.6.

In one example, the trench portions in the upper surface of the layer of piezoelectric material are also overlapped with at least part of the gap regions.

In one example, the trench portions each have a length that extends from the edge region of one of the pair of interdigital transducer electrodes to the bus bar of the other of the pair of interdigital transducer electrode.

In one example, each of the interdigital transducer electrodes includes a second bus bar that is located within the gap region.

In one example, the trench portions each have a width in a direction perpendicular to the direction of propagation of an acoustic wave to be generated by the pair of interdigital transducer electrodes that extends from the respective edge region to the second bus bar of the other interdigital transducer electrode.

In one example, the layer of piezoelectric material is formed of a material selected from the group consisting of lithium tantalate, aluminum nitrate, lithium niobate, and potassium niobate.

In one example, the layer of dielectric material includes silicon dioxide or doped silicon material.

In one example, the carrier substrate is formed of a material selected from the group consisting of silicon, aluminum nitride, silicon nitride, magnesium oxide spinel, magnesium oxide crystal, quartz, diamond, diamond-like carbon, and sapphire.

In one example, the carrier substrate comprises a first layer of substrate including silicon, silicon carbide, sapphire, quartz, diamond, or diamond like carbon, and a second layer of substrate including aluminum nitride, silicon nitride, polycrystalline silicon, or amorphous silicon, the second layer of substrate having a lower surface disposed against an upper surface of the first layer of substrate, and an upper surface disposed against the lower surface of the layer of dielectric material.

In one example, each interdigital transducer electrode is formed from a single layer of etch resistant material.

In one example, the etch resistant material is selected from the group consisting of copper, platinum, tungsten, molybdenum, ruthenium, iridium, gold, and silver.

In one example, each interdigital transducer electrode is formed from one or more lower layers of material and an upper layer of etch resistant material.

In one example, the etch resistant material is selected from the group consisting of copper, platinum, tungsten, molybdenum, ruthenium, iridium, gold, and silver.

In one example, each interdigital transducer electrode includes a mask layer on an upper surface of the interdigital transducer electrode.

In one example, the mask layer is a layer of chromium.

In one example, there further comprises a protective layer disposed over upper surfaces of the pair of interdigital transducer electrodes and the layer of piezoelectric material.

In one example, the protective layer is formed from one or more of the group consisting of silicon nitride, silicon oxynitride, and silicon dioxide.

According to another embodiment there is provided a radio frequency (RF) ladder filter comprising a set of series resonators connected in series between an input and an output of the RF ladder filter, the set of series resonators including at least one of a first type of acoustic wave device, the first type of acoustic wave device including a carrier substrate, a layer of dielectric material having a lower surface disposed against an upper surface of the carrier substrate, a layer of piezoelectric material having a lower surface disposed against an upper surface of the layer of dielectric material, a pair of interdigital transducer electrodes disposed on an upper surface of the layer of piezoelectric material, each interdigital transducer electrode including a bus bar, and a plurality of electrode fingers extending from the bus bar to distal ends of the electrode fingers at an edge region of the interdigital transducer electrode, and trench portions located in the upper surface of the layer of piezoelectric material, said trench portions being overlapped by the edge regions of the interdigital transducer electrodes, the electrode fingers having a uniform width, and a set of parallel resonators connected in parallel between the acoustic devices of the set of series resonators and ground in a shunt configuration, the set of parallel resonators including at least one of a second type of acoustic wave device, the second type of acoustic wave device including a carrier substrate, a layer of dielectric material having a lower surface disposed against an upper surface of the carrier substrate, a layer of piezoelectric material having a lower surface disposed against an upper surface of the layer of dielectric material, a pair of interdigital transducer electrodes disposed on an upper surface of the layer of piezoelectric material, each interdigital transducer electrode including a bus bar, and a plurality of electrode fingers extending from the bus bar to distal ends of the electrode fingers at an edge region of the interdigital transducer electrode, and trench portions located in the upper surface of the layer of piezoelectric material, said trench portions overlapping with the edge regions of the interdigital transducer electrodes, the electrode fingers having regions at their distal ends that have a reduced width, the reduced width region having lengths of between about 1.1λ and 1.2λ, where λ is the wavelength of the acoustic wave to be generated.

In one example, the first type of acoustic wave device comprises trench portions each having a first width and the second type of acoustic wave device comprises trench portions each having a second width, the second width being larger than the first width.

In one example, the first width is between about 0.8λ and 1.0λ.

In one example, the set of series resonators comprises only acoustic wave devices of the first type.

In one example, the set of parallel resonators comprises only acoustic wave devices of the second type.

In one example, the set of parallel resonators comprises a mixture of acoustic wave devices of the first and second types.

According to another embodiment there is provided an electronics module comprising at least one radio frequency filter that includes at least one acoustic wave device, the at least one acoustic wave device including a carrier substrate, a layer of dielectric material having a lower surface disposed against an upper surface of the carrier substrate, a layer of piezoelectric material having a lower surface disposed against an upper surface of the layer of dielectric material, a pair of interdigital transducer electrodes disposed on an upper surface of the layer of piezoelectric material, each interdigital transducer electrode including a bus bar, and a plurality of electrode fingers extending from the bus bar to distal ends of the electrode fingers at an edge region of the interdigital transducer electrode, and trench portions located in the upper surface of the layer of piezoelectric material, said trench portions being overlapped by the edge regions of the interdigital transducer electrodes, the electrode fingers having regions at their distal ends that have a reduced width, the reduced width region having a length of between about 1.1λ and 1.2λ, where λ is the wavelength of the acoustic wave to be generated.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment,” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the various aspects and embodiments. In the figures, each identical or nearly identical component that is illustrated in various figures is represented by a like numeral. For purposes of clarity, not every component may be labeled in every figure. In the figures:

FIG. 1A is a cross-sectional side view of an acoustic wave device;

FIG. 1B is a plan view of the acoustic wave device of FIG. 1A;

FIG. 2A is a plan view of an acoustic wave device;

FIG. 2B is a cross-sectional view of the acoustic wave device of FIG. 2A;

FIG. 2C is a cross-sectional view of the acoustic wave device of FIG. 2A;

FIG. 2D is a cross-sectional view of the acoustic wave device of FIG. 2A;

FIG. 2E is a cross-sectional view of the acoustic wave device of FIG. 2A;

FIG. 3A is a graph showing a comparison of admittance curves of the acoustic wave device of FIG. 2A and the acoustic wave device of FIG. 1A;

FIG. 3B is a graph showing a comparison of admittance curves of the acoustic wave device of FIG. 2A and the acoustic wave device of FIG. 1A;

FIG. 3C is a graph showing a comparison of quality factor curves of the acoustic wave device of FIG. 2A and the acoustic wave device of FIG. 1A;

FIG. 4A is a plan view of an alternative acoustic wave device;

FIG. 4B is a cross-sectional view of the acoustic wave device of FIG. 4A;

FIG. 4C is a cross-sectional view of the acoustic wave device of FIG. 4A;

FIG. 4D is a cross-sectional view of the acoustic wave device of FIG. 4A;

FIG. 4E is a cross-sectional view of the acoustic wave device of FIG. 4A;

FIG. 5A is a graph showing a comparison of admittance curves of the acoustic wave device of FIG. 2A and the acoustic wave device of FIG. 4A;

FIG. 5B is a graph showing a comparison of admittance curves of the acoustic wave device a of FIG. 2A and the acoustic wave device of FIG. 4A;

FIG. 5C is a graph showing a comparison of quality factor curves of the acoustic wave device of FIG. 2A and the acoustic wave device of FIG. 4A;

FIG. 6 is a schematic diagram showing the how variations in the width of the IDT fingers (w) compared to the width of the spacing between the same part of the IDT fingers (p) sets the duty factor (DF);

FIG. 7A is a graph showing an example of transmission characteristics in response to frequency for a filter, showing spikes causes by transverse modes;

FIG. 7B is a graph showing an example of admittance curves of a resonator in response to frequency, showing spikes caused by transverse modes;

FIG. 8 is a graph showing admittance curves for a number of devices with various slow region lengths (i.e., the length of the reduced width region at the distal ends of the electrode fingers);

FIG. 9A is a plan view of an acoustic wave device;

FIG. 9B is a cross-sectional view of the acoustic wave device of FIG. 9A;

FIG. 9C is a cross-sectional view of the acoustic wave device of FIG. 9A;

FIG. 9D is a cross-sectional view of the acoustic wave device of FIG. 9A;

FIG. 9E is a cross-sectional view of the acoustic wave device of FIG. 9A;

FIG. 10A is a graph showing a comparison of admittance curves of various acoustic wave devices;

FIG. 10B is a graph showing a comparison of admittance curves of various acoustic wave devices;

FIG. 10C is a graph showing a comparison of quality factor curves of various acoustic wave devices;

FIG. 11 shows an example of a ladder filter in which multiple acoustic wave devices according to aspects disclosed herein may be combined;

FIG. 12 shows an example of a ladder filter according to aspects disclosed herein;

FIG. 13 shows an example of an alternative ladder filter according to aspects disclosed herein;

FIG. 14 is a block diagram of one example of a filter module that can include one or more acoustic wave devices according to aspects of the present disclosure;

FIG. 15 is a block diagram of one example of a front-end module that can include one or more filter modules including acoustic wave devices according to aspects of the present disclosure; and

FIG. 16 is a block diagram of one example of a wireless device including the front-end module of FIG. 15.

### DETAILED DESCRIPTION

An acoustic wave device, a radio frequency ladder filter, and an electronics module are provided. The acoustic wave device comprises a carrier substrate, a layer of dielectric material, a layer of piezoelectric material, a pair of interdigital transducer electrodes each including a bus bar and a plurality of electrode fingers extending from the bus bar to the distal ends of the electrode fingers at an edge region of the interdigital transducer electrode, and trench portions located in the upper surface of the layer of piezoelectric material, said trench portions being overlapped by the edge regions of the interdigital transducer electrodes, the electrode fingers having regions at their distal ends that have a reduced width, the reduced width regions having lengths of between about 1.1λ and 1.2λ, where λ is the wavelength of the acoustic wave to be generated. The acoustic wave device provides effective suppression of transverse modes.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

Aspects and embodiments are described below through embodiments of acoustic wave devices, in particular surface acoustic wave (SAW) devices. However, as would be understood by the skilled person, various different excitation modes are possible in acoustic wave filters and devices, particularly multilayer piezoelectric substrate (MPS) devices. As well as surface acoustic waves other types of acoustic wave are possible such as boundary acoustic waves and guided acoustic waves. References to surface acoustic waves and surface acoustic wave devices in the following description are not intended to limit the disclosure from including or covering other possible types of acoustic waves and acoustic wave devices.

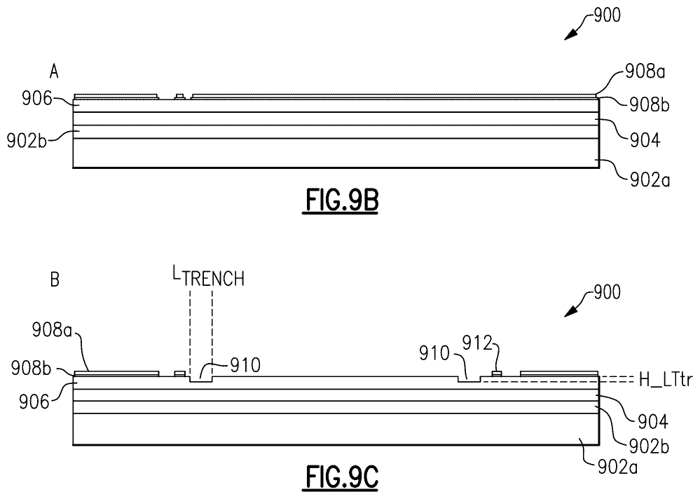

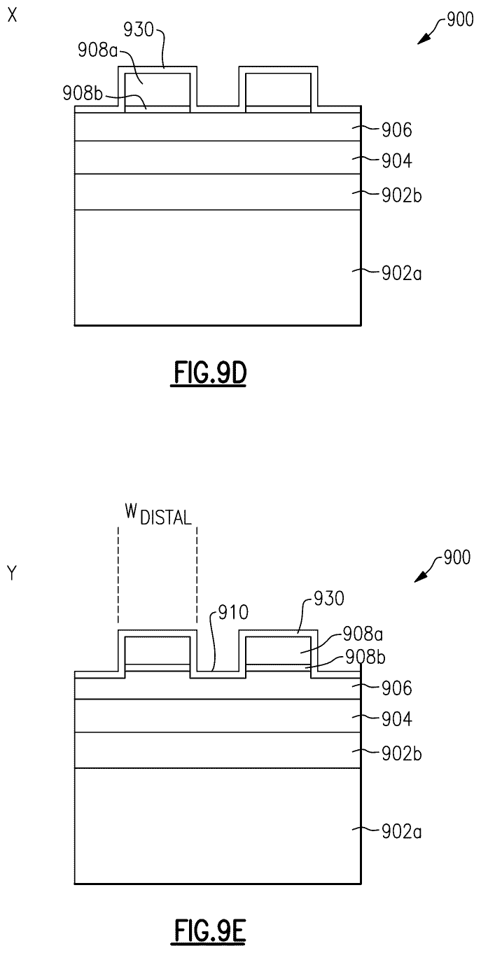

FIGS. 9A-9E show an acoustic wave device 900. The acoustic wave device 900 includes a carrier substrate having carrier substrate layers 902a and 902b (referred to herein together as carrier substrate 902), a layer of dielectric material 904, a layer of piezoelectric material 906, an interdigital transducer (IDT) 908 with an upper IDT layer 908a and a lower IDT layer 908b, and trench portions 910 located in the upper surface of the layer of piezoelectric material 906. The device 900 may optionally include a protective layer 930.

It is to be understood that further, unspecified layers may also be included below the acoustic wave device 900 (i.e., below carrier substrate layer 902a) or above the acoustic wave device 900 (i.e., above the IDT layer 908a or protective layer 930). This may occur when the acoustic wave device 900 is used in a component of another device, such as a SAW filter, to hold the component in place whilst in use.

The carrier substrate may be formed of a single carrier substrate layer 902a. The carrier substrate may be formed of a material having a lower coefficient of linear expansion and/or a higher thermal conductivity and/or a higher toughness or mechanical strength than the piezoelectric material forming the layer of piezoelectric material 906. The carrier substrate 902 may both increase the mechanical robustness of the piezoelectric material during fabrication of the SAW device and increase manufacturing yield, as well as reduce the amount by which operating parameters of the SAW device change with temperature during operation. The carrier substrate 902 may be referred to as a high impedance support substrate.

The carrier substrate may be formed of two layers, 902a and 902b, with the second carrier substrate layer 902b being disposed between the first carrier substrate layer 902a and the layer of dielectric material 904. The second carrier substrate layer 902b may act as a trap-rich layer, and can be used to improve the effective resistivity of the substrate layers.

The first carrier substrate layer 902a may comprise or consist of silicon, silicon carbide, sapphire, quartz, diamond, or diamond-like carbon. The second carrier substrate layer 902b may comprise or consist of aluminum nitride (AlN), silicon nitride (Si₃N₄), polycrystalline silicon (poly-Si), or amorphous silicon (A-Si).

The layer of dielectric material 904 may have a lower surface disposed against an upper surface of the carrier substrate layer 902a (or 902b if this optional layer is included). The layer of dielectric material 904 may comprise or consist of silicon dioxide (SiO₂) or doped silicon material such as F doped SiO₂ or Ti doped SiO₂.

The layer of piezoelectric material 906 may have a lower surface disposed against an upper surface of the layer of dielectric material 904. Any piezoelectric material may be used as the layer of piezoelectric material 906, for example, including but not limited to lithium tantalate (LiTaO₃), aluminum nitrite (AlN), lithium niobate (LiNbO₃), or potassium niobate (KNbO₃).

An interdigital transducer (IDT) 908 is disposed on top of the layer of piezoelectric material 906 and is configured to generate a surface acoustic wave in the multilayer piezoelectric substrate. In use, the IDT 908 excites a main acoustic wave having a wavelength λ along a surface of the multilayer piezoelectric substrate. The acoustic wave is concentrated in the top two layers (the layer of dielectric material 904 and layer of piezoelectric material 906). The carrier substrate 902 (formed of, e.g., silicon) may have a high impedance meaning the acoustic wave is reflected at the boundary between the carrier substrate 902 and the layer of dielectric material 904, confining the surface acoustic wave in the top two layers. In some embodiments, the thickness of the layer of dielectric material 904 may be between 0.1λ and 1λ, and the thickness of the layer of piezoelectric material 906 may be between 0.1λ and 1λ, where λ is the wavelength of an acoustic wave generated by the IDT in operation. It is to be understood that the dimensions above are only examples and may be set at different values in different embodiments of acoustic wave devices to achieve different design goals.

Any type of IDT may be used as the IDT 908 in the acoustic wave device 900. For example, the IDT 908 may include a pair of interlocking comb-shaped IDT electrodes. Each comb-shaped electrode of the IDT includes a bus bar and a plurality of electrode fingers that extend perpendicularly from the bus bar. Typically the distance between the central point of each adjacent electrode finger extending from the same bus bar is equal to the wavelength λ of the surface acoustic wave generated. The bus bars of each of the pair of IDT electrodes are parallel and opposing each other, and the plurality of electrode fingers of each IDT electrode extend towards to the bus bar of the opposing electrode, such that the electrode fingers interlock, typically with a distance of λ/2 between the center of each adjacent electrode finger extending from opposite bus bar. The main surface acoustic wave generated by the IDT travels perpendicular to the lengthwise direction of the IDT electrode fingers, and parallel to the lengthwise direction of the IDT bus bars.

Regardless of the type of IDT used, the IDT 908 has an active region defined as the region in which the fingers of each IDT electrode interleave with one another. The surface acoustic wave is generated in the active region of the IDT. The active region of the IDT includes a central region and two edge regions. The central region is labeled by the letter C in FIG. 9A and the edge regions are labeled by the letter E. Each edge region E extends from the tips of the plurality of fingers of one of the electrodes towards the center of the central region C. In other words, the edge regions E include end portions of the IDT electrode fingers, and the central region C is sandwiched between the edge regions. The IDT also includes gap regions located between the ends of the fingers of one of the electrodes and the bus bar of the other electrode. The dashed lines in FIG. 9A show the boundaries between the above described regions.

In the embodiment of FIG. 9A, the electrodes of the IDT 908 each include a second bus bar 912. The second bus bars 912 extend parallel to the bus bars, and are located adjacent to the edge regions E of the IDT 908. The second bus bars 912 are thinner than the bus bars, and may be referred to as “mini bus bars.” The mini bus bars result in the transverse modes being suppressed more effectively. However, in some embodiments these mini bus bars may be omitted. Whilst the suppression of the transverse modes is improved when the acoustic wave device includes the mini bus bars 912, compared to when the mini bus bars are omitted, the inclusion of mini bus bars 912 is optional.

In the embodiments of FIGS. 9A-9E a double layer IDT 908 is used, with an upper IDT layer 908a and a lower IDT layer 908b. However single layer IDTs may also be used. In general various IDT structures are possible, as would be understood by the skilled person, for example double electrode IDTs, or IDTs with dummy electrode fingers may be used. Specific IDT configurations will be discussed in more detail later, taking into consideration the method of manufacture of the device.

The IDT may be formed from a single layer of etch resistant material, chosen to protect the exposed sections of the IDT 908 during an etching process. A multilayer IDT may be used with an upper IDT layer 908a and a lower IDT layer 908b. In embodiments with such IDT configurations, a high density IDT material that is etch resistant may be chosen as the upper IDT layer 908a. The high density upper IDT layer means that the exposed sections of the IDT are protected during the etching process, even when not covered by an etching mask. The high density upper IDT layer also means that the surface of the piezoelectric material underneath the IDT is protected and therefore not removed during the etching process.

The high density IDT material of the upper IDT layer may be any of copper (Cu), platinum (Pt), tungsten (W), molybdenum (Mo), ruthenium (Ru), iridium (Ir), gold (Au), or silver (Ag). Preferably, copper is chosen as the high density material for the upper IDT layer 908a, as it is resistant to etching chemicals as well as being highly conductive, meaning resistive loss is reduced.

The lower IDT layer 908b can include materials that are not etch resistant, such as aluminum (Al), due to the high density upper IDT layer. However, other materials that are etch resistant may still be used as the lower layer in some embodiments, for example, a Cu lower layer. In some embodiments, the IDT may include multiple lower IDT layers underneath the upper IDT layer.

In a specific embodiment, a high density Mo layer may be used as the upper IDT layer 908a, and lower density but higher conductivity Al may be used as the lower IDT layer 908b.

In general, the IDT may be formed through one or more of mask printing, deposition such as physical vapor deposition, electroplating, a lift-off process, a dry etching process, or the like. A lift-off process is preferred.

The acoustic wave device 900 further includes trench structures in the layer of piezoelectric material 906 for suppressing the transverse modes. Trench portions 910 are located in the upper surface of the layer of piezoelectric material 906. The trench portions 910 overlap with the edge regions E of the IDT 908. In other words, the trench portions 910 are located within the active region of the IDT 908, in the edge regions E of the IDT 908, and form a boundary of the active region running parallel with the bus bars. The trench portions 910 slow down the acoustic velocity at the edge of the active region to create a piston mode acoustic wave distribution, and thus suppress the transverse modes. The trench structures may preferably have a depth relative to the upper surface of the layer of piezoelectric material of between about 0.004λ and 0.02λ, or alternatively a depth of around 15 nm. The trench portions may have a length (i.e., extending lengthwise between the central and edge regions of the device, perpendicular to the direction in which waves are generated whilst in use) of between about 0.5λ and 1λ.

As can be seen from FIG. 9A, the trench portions 910 extend parallel to the bus bars, in the direction of propagation of the main acoustic wave generated by the IDT 908. However, the trench portions 910 are only present in the sections of the upper surface of the layer of piezoelectric material 906 that are overlapped by the edge regions E of the IDT 908 and are not covered by the material of the IDT 908. In other words, the trench portions 910 are only cut into the surface of the layer of piezoelectric material 906 that is exposed after the IDT 908 has been formed on the layer of piezoelectric material 906. The trench portions 910 are not cut into the sections of the layer of piezoelectric material 906 covered by the IDT 908, meaning the trench portions 910 do not run underneath the IDT 908. The layer of piezoelectric material 906 remains at full thickness underneath the IDT 908. This is best seen in FIG. 9E, showing the trench portions 910 cut into the upper surface of the layer of piezoelectric material 906 not covered by the IDT 908, and not cut into the upper surface of the layer of piezoelectric material 906 covered by the IDT 908. A comparison of the cross-sectional views of FIGS. 9B and 9C also shows this. Therefore, the trench portions 910 can be described as extending discontinuously in the direction of propagation of the main acoustic wave generated by the IDT 908 (along the line marked Y in FIG. 9A).

The trench portions 910 can be formed by etching the layer of piezoelectric material 906. In particular, the trench portions 910 may be etched after the formation of the IDT 908 on the upper surface of the layer of piezoelectric material 906, with the IDT preventing etching of the layer of piezoelectric material 906 underneath the IDT.

It can be seen in FIG. 9A that the electrode fingers of the IDT 908 are not of uniform width. Instead, the electrode fingers include thinner tip portions which are sections of each of the plurality of electrode fingers in the IDT 908 that have a width in a direction perpendicular to the extension of the electrode fingers that is smaller in the edge regions E of the IDT electrodes than in the central regions C of the IDT electrodes. The thinner tip portions may be referred to as “reduced width portions” of the electrode fingers or portions of the electrode fingers “that have a reduced width” herein. The reduced width tip portions are located in the edge region E of each IDT electrode. In other words, the distal ends of the plurality of electrode fingers in each IDT electrode have a reduced width, W_{Distal}. The reduced width tip portions are also located at the sections of each IDT electrode that overlap with the edge region E of the other IDT electrode. The widths of the plurality of electrode fingers of each IDT electrode are therefore smaller in both the edge region E of that IDT electrode and the edge region E of the other IDT electrode, as best seen in the view of FIG. 9A.

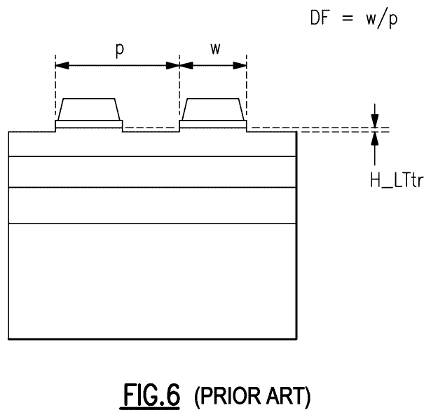

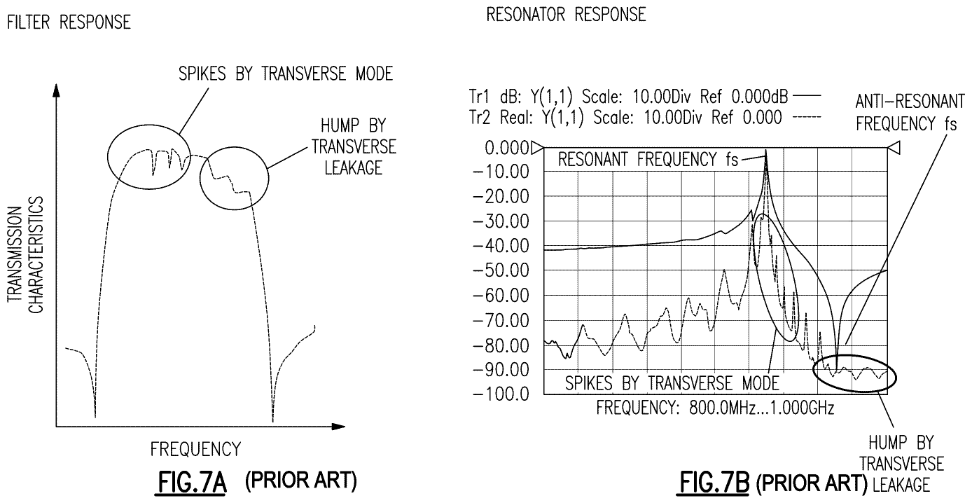

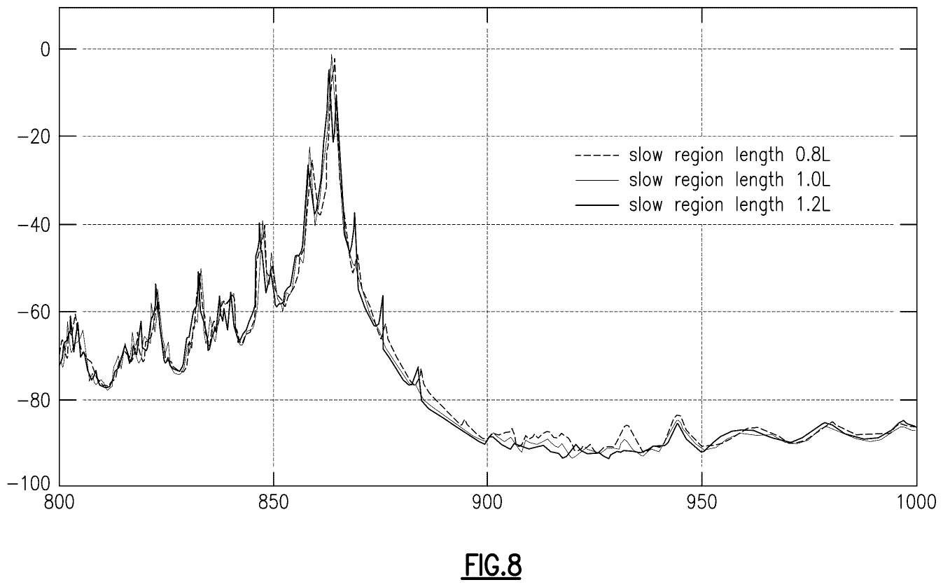

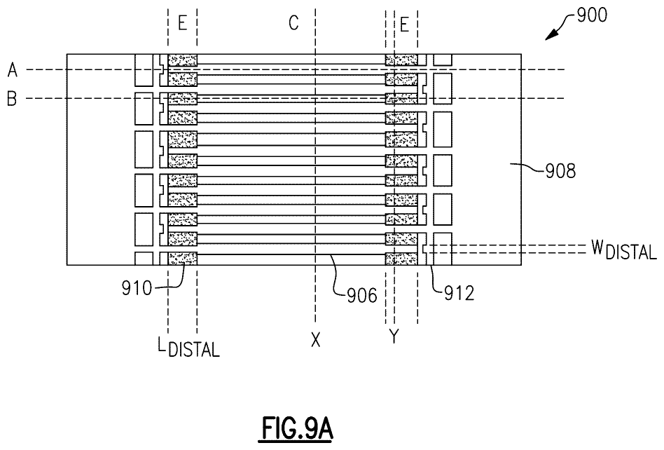

A duty factor (DF) of the pair of IDT electrodes in the edge regions E is smaller than a duty factor of the pair of IDT electrodes in the central region C. The duty factor at the distal ends of the electrode fingers may preferably be about 0.4, with the rest of the electrode fingers having a duty factor of around 0.5. The reasoning as to why the reduced width of the tip portions leads to a reduced DF compared to the central portion of the electrode fingers can be understood from the duty factor diagram shown in FIG. 6.

These reduced width portions of the electrode fingers may have an increased length (i.e. in the direction perpendicular to the direction of propagation of an acoustic wave to be generated by the pair of interdigital transducer electrodes) compared to prior art designs, such as the acoustic wave device 400. For example, the reduced width portions of the electrode fingers of the acoustic wave device 400 may have a length of 1.0λ or less. The acoustic wave device 900 includes reduced width portions of the electrode fingers with lengths of between about 1.1λ and 1.2λ. It should be noted that other acoustic wave devices could include reduced width portions of the electrode fingers with lengths larger than this range, for example, 1.3λ or 1.4λ, or within the range of any of these quoted values.

FIG. 8 shows how variations in the lengths of such reduced width portions (which may also be referred to as slow regions) can effect the presence of transverse spikes. As shown in this diagram, reduced width portions of length 0.8λ perform worst in avoiding creating transverse spikes and transverse leakages. Reduced width portions of length 1.0λ improve upon the 0.8λ lengths, particularly in suppressing transverse spikes. Reduced width portions of length 1.2λ perform similarly to the 1.0λ lengths in reducing transverse spikes and best of all at reducing transverse leakage. The 1.2λ length reduced width portions also have the advantage of allowing for the lightest device weight of these three examples.

The acoustic wave device 900 may additionally include an optional protective layer 930 disposed on top of the upper surfaces of the pair of interdigital transducer electrodes and the layer of piezoelectric material 906. This protective layer 930 is shown in FIGS. 9D and 9E. The protective layer is applied to the acoustic wave device 900 after the trench portions 910 have been formed in the layer of piezoelectric material 906 (e.g., via etching). The protective layer 930 helps to protect the IDT from chemical and physical damage during fabrication processing, and protects the IDT from humidity or other chemical damage after fabrication. Additionally, the protective layer 930 can help to protect the IDT from mechanical migration or loss of material in the upper layer of piezoelectric material 906 or IDT layers 908a, 908b when in use. The protective layer 930 may comprise silicon nitride (SiN), silicon oxynitride (SiON), and/or silicon dioxide (SiO₂).

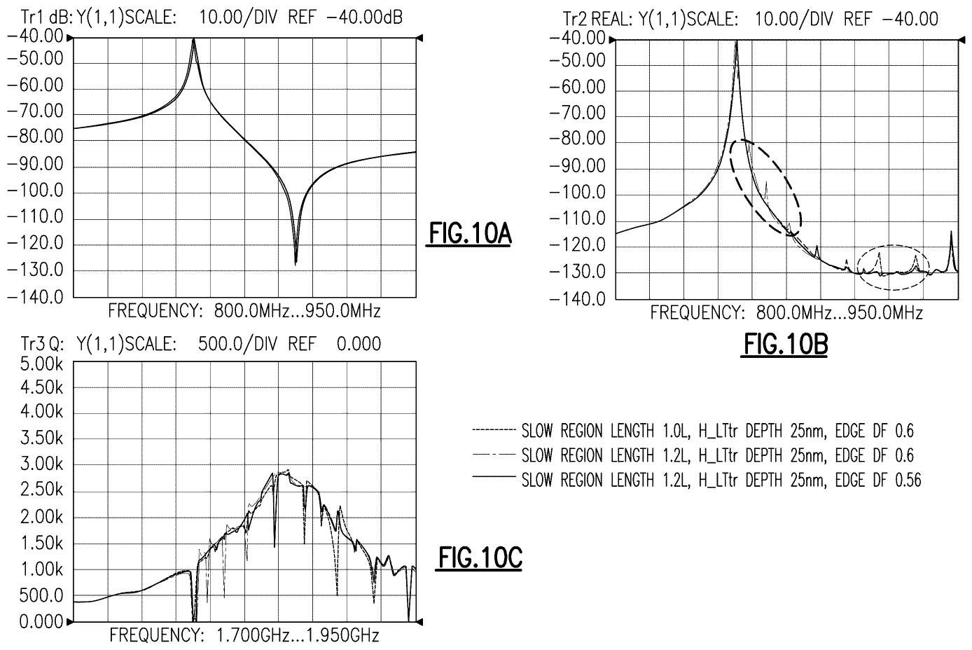

FIGS. 10A to 10C are simulation graphs showing a comparison between admittance curves (complex FIG. 10A, and real FIG. 10B) and quality factor curves (Q-factor, FIG. 10C) of various acoustic wave devices. The devices all have a trench depth of 25 nm, but with variations in the slow region length (reduced width portion length) and edge duty factor (i.e., the reduced width portion width). As can be seen from these diagrams, (in particular FIG. 10B) the slow region length=1.0λ and edge duty factor=0.6 line includes transverse mode spikes, and the slow region length=1.2λ and edge duty factor=0.6 line includes transverse mode leakage. It is the slow region length=1.2λ and edge duty factor=0.56 line (i.e., the device which includes reduced width tip portions and increased tip lengths) which performs best as suppressing both of these phenomena.

The embodiments of the acoustic wave device disclosed herein may be used in various different implementations. In general the acoustic wave device may be used in any device that includes an IDT. For example, the acoustic wave device may be used in various types of acoustic wave resonators and/or filters, including 1-port resonators, 2-port resonators, ladder filters, and the like. In a resonator configuration, one or more reflector electrodes may be included surrounding/sandwiching the IDT. Although the embodiments above have been described with only one IDT, other configurations are possible, as would be understood by the skilled person.

It should be appreciated that the various embodiments of acoustic wave devices illustrated in the figures, as well as the other circuit elements illustrated in other figures presented herein, are illustrated in a highly simplified form. The relative dimensions of the different features are not shown to scale. Further, typical acoustic wave devices would commonly include a far greater number of electrode fingers in the IDTs than illustrated.

The concepts and embodiments of acoustic wave devices described herein are applicable to various types of devices, as would be understood by the skilled person. For example, aspects and embodiments disclosed herein may be applied to filters, duplexers, diplexers or the like. The suppression of transverse modes in the above described acoustic wave devices may lead to an overall improvement in the overall functioning of the circuit.

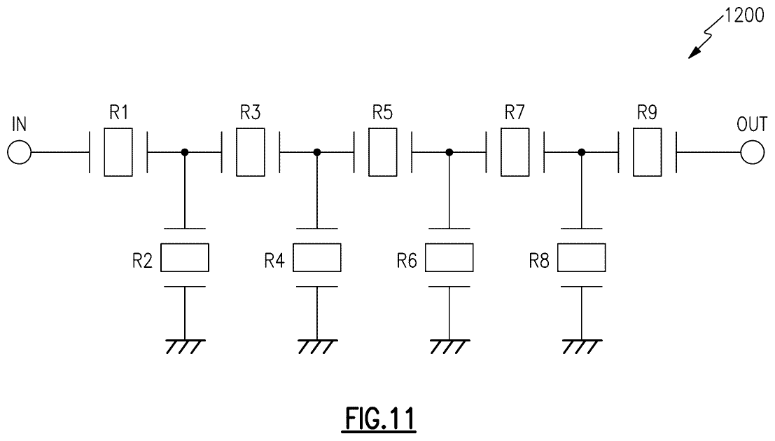

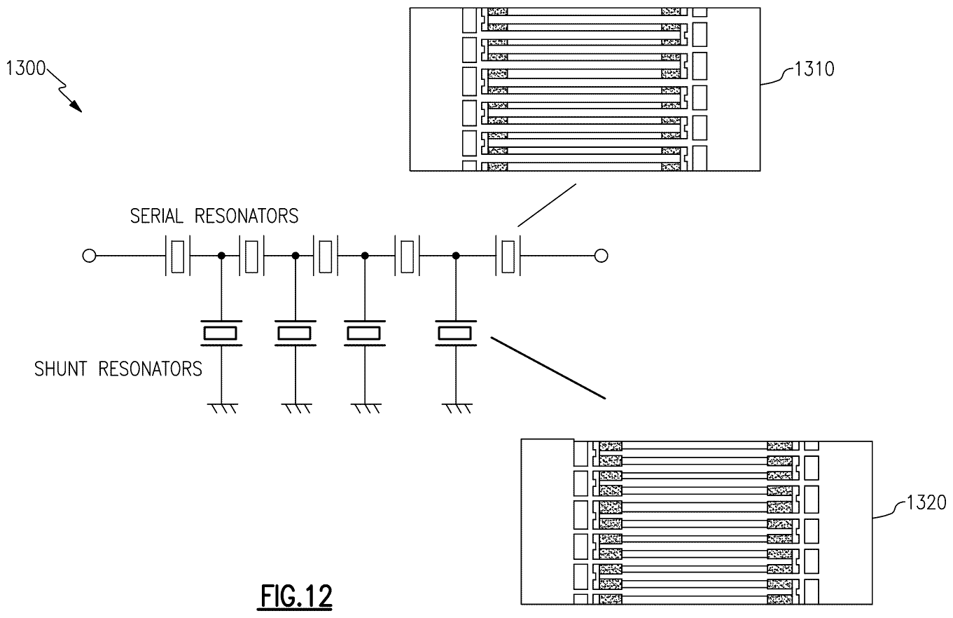

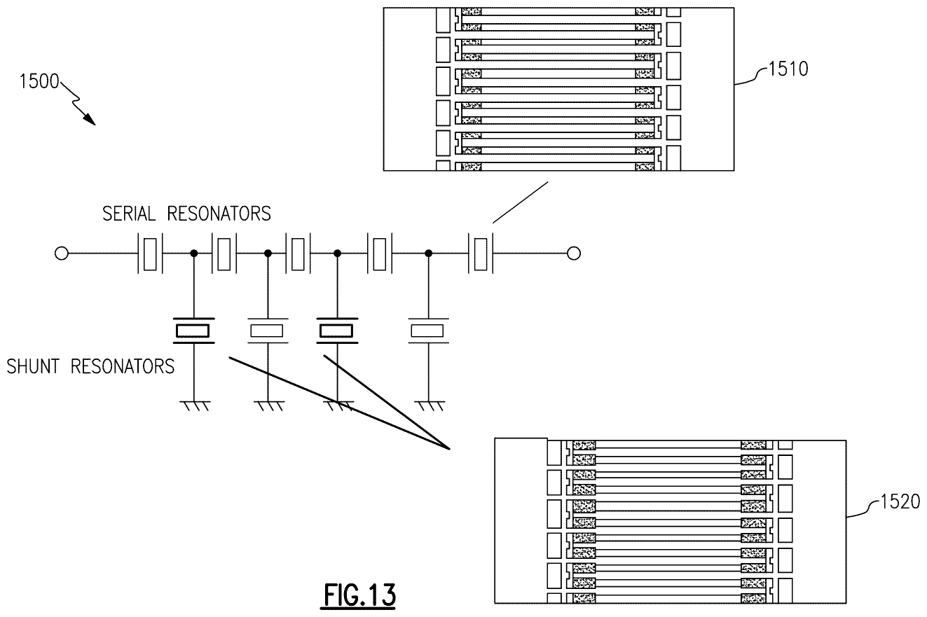

FIG. 11 shows an example of a SAW filter 1200 in which multiple acoustic wave devices as disclosed herein may be combined. FIG. 11 shows an RF ladder filter 1200 including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of acoustic wave devices as disclosed herein.

When constructing a SAW filter as shown in FIG. 11, the inventors of the present application have identified that it can be beneficial to select the topology of the various series and shunt resonators in order to sculpt the desired characteristics of the SAW filter.

FIG. 12 shows an example of a SAW filter 1300. As discussed above, the SAW filter includes a set of series resonators and a set of shunt resonators. The set of series resonators for the SAW filter 1300 are made entirely of a first type of acoustic wave device 1310. In this example, the acoustic wave devices 1310 are each constructed as an acoustic wave device 200. The set of shunt resonators for SAW filter 1300 are made entirely of a second type of acoustic wave device 1320. In this example, the acoustic wave devices 1320 are each constructed as an acoustic wave device 900.

FIG. 13 shows another example of a SAW filter 1500. The SAW filter includes a set of series resonators and a set of shunt resonators. The set of series resonators for SAW filter 1500 are made entirely of a first type of acoustic wave device 1510. In this example, the acoustic wave devices 1510 are each constructed as an acoustic wave device 200. The set of shunt resonators for SAW filter 1500 are made of a mixture of the first type of acoustic wave device 1510, and a second type of acoustic wave device 1520. In this example, the acoustic wave devices 1520 are each constructed as an acoustic wave device 900. The ratio of the first type of acoustic wave device to the second type of acoustic wave device in the set of shunt resonators may be varied to determine the response characteristics of the final SAW filter 1500. In the example shown, the ratio of the first and second types is 1:1. However, this ratio could be varied, for example, as 1:2 or 2:1.

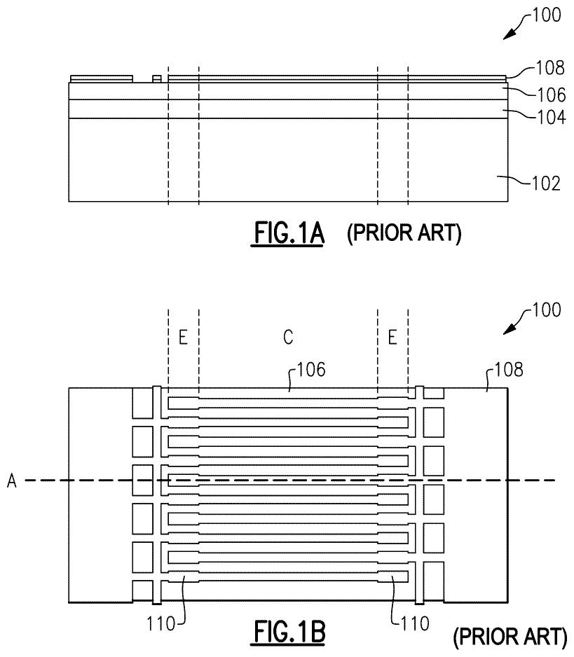

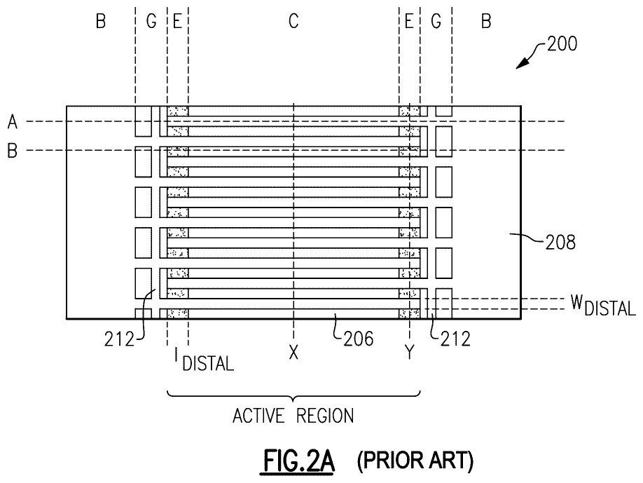

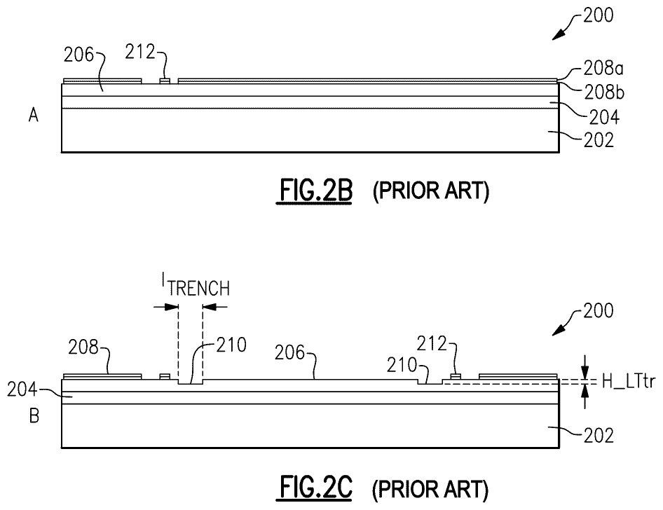

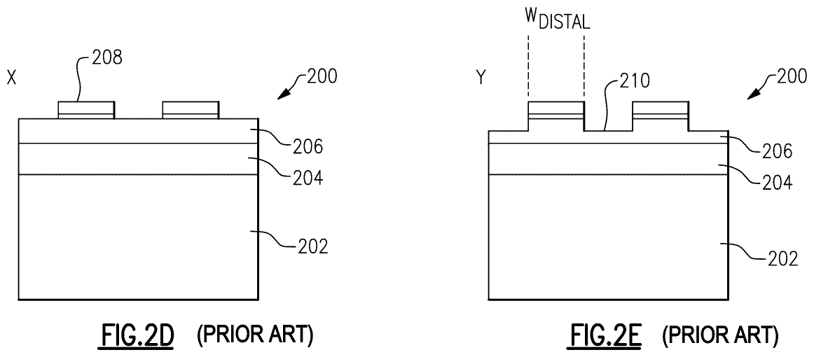

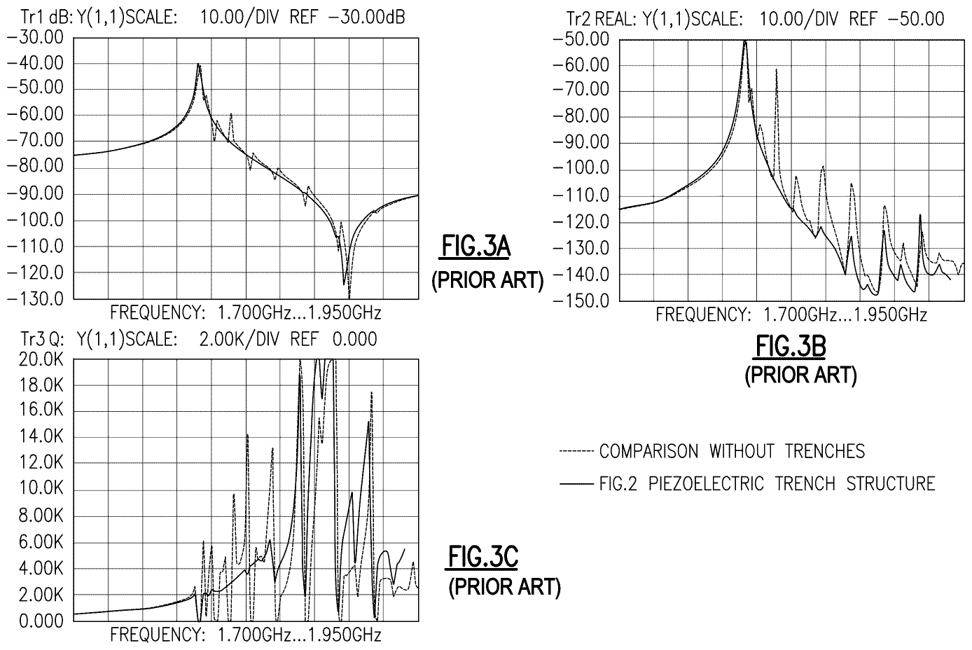

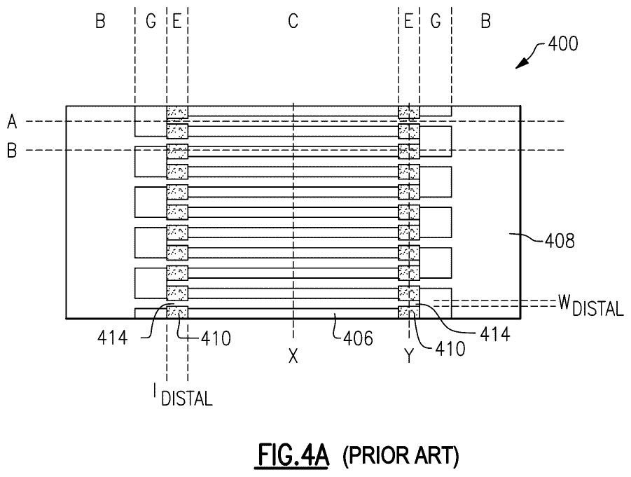

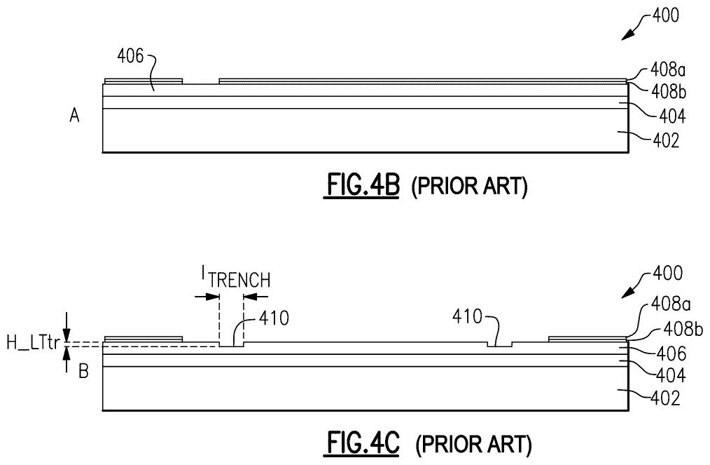

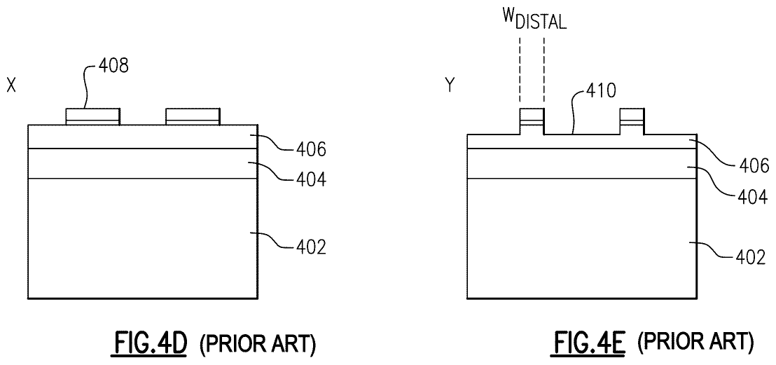

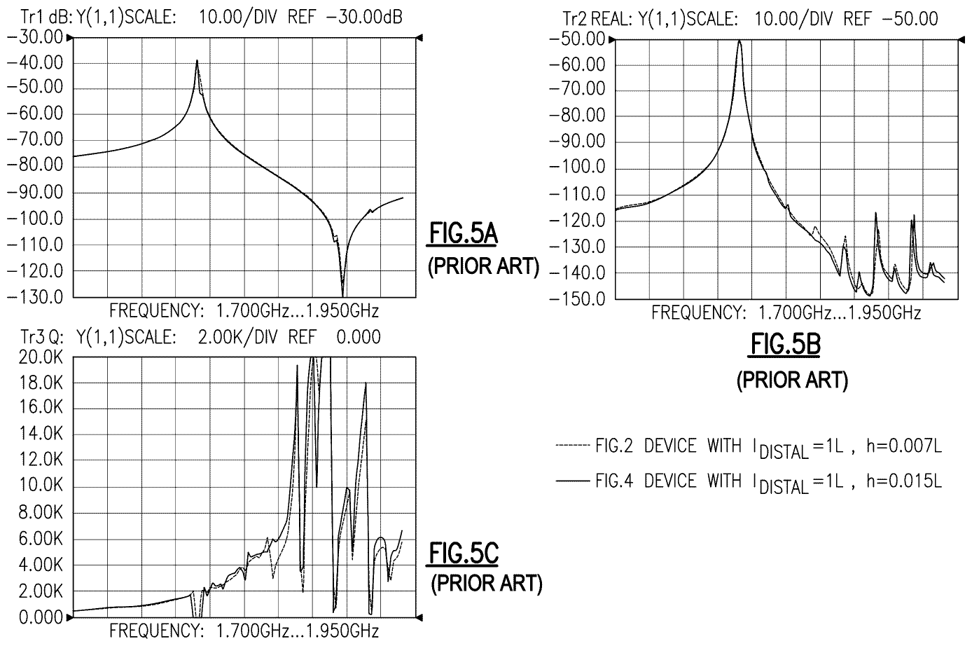

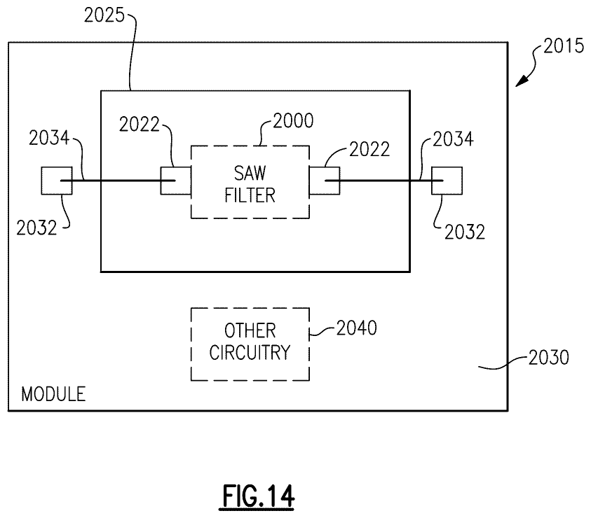

As discussed above, acoustic wave devices, such as those of FIGS. 1, 2A-2E, 4A-4E, and 9A-9E, can be used in radio frequency (RF) filters. In turn, an RF filter such as a SAW filter may be incorporated into and packaged as a module that may ultimately be used in an electronic device, such as a wireless communications device, for example. FIG. 14 is a block diagram illustrating one example of a module 2015 including a SAW filter 2000. The SAW filter 2000 may be implemented on one or more die(s) 2025 including one or more connection pads 2022. For example, the SAW filter 2000 may include a connection pad 2022 that corresponds to an input contact for the SAW filter and another connection pad 2022 that corresponds to an output contact for the SAW filter. The packaged module 2015 includes a packaging substrate 2030 that is configured to receive a plurality of components, including the die 2025. A plurality of connection pads 2032 can be disposed on the packaging substrate 2030, and the various connection pads 2022 of the SAW filter die 2025 can be connected to the connection pads 2032 on the packaging substrate 2030 via electrical connectors 2034, which can be solder bumps or wirebonds, for example, to allow for passing of various signals to and from the SAW filter 2000. The module 2015 may optionally further include other circuitry die 2040, for example, one or more additional filter(s), amplifiers, pre-filters, modulators, demodulators, down converters, and the like, as would be known to one of skill in the art of semiconductor fabrication in view of the disclosure herein. In some embodiments, the module 2015 can also include one or more packaging structures to, for example, provide protection and facilitate easier handling of the module 2015. Such a packaging structure can include an overmold formed over the packaging substrate 2030 and dimensioned to substantially encapsulate the various circuits and components thereon.

Various examples and embodiments of the SAW filter 2000 can be used in a wide variety of electronic devices. For example, the SAW filter 2000 can be used in an antenna duplexer, which itself can be incorporated into a variety of electronic devices, such as RF front-end modules and communication devices.

Referring to FIG. 15, there is illustrated a block diagram of one example of a front-end module 2100, which may be used in an electronic device such as a wireless communications device (e.g., a mobile phone) for example. The front-end module 2100 includes an antenna duplexer 2110 having a common node 2102, an input node 2104, and an output node 2106. An antenna 2210 is connected to the common node 2102.

The antenna duplexer 2110 may include one or more transmission filters 2112 connected between the input node 2104 and the common node 2102, and one or more reception filters 2114 connected between the common node 2102 and the output node 2106. The passband(s) of the transmission filter(s) are different from the passband(s) of the reception filters. Examples of the SAW filter 2000 can be used to form the transmission filter(s) 2112 and/or the reception filter(s) 2114. An inductor or other matching component 2120 may be connected at the common node 2102.

The front-end module 2100 further includes a transmitter circuit 2132 connected to the input node 2104 of the duplexer 2110 and a receiver circuit 2134 connected to the output node 2106 of the duplexer 2110. The transmitter circuit 2132 can generate signals for transmission via the antenna 2210, and the receiver circuit 2134 can receive and process signals received via the antenna 2210. In some embodiments, the receiver and transmitter circuits are implemented as separate components, as shown in FIG. 15, however, in other embodiments these components may be integrated into a common transceiver circuit or module. As will be appreciated by those skilled in the art, the front-end module 2100 may include other components that are not illustrated in FIG. 15 including, but not limited to, switches, electromagnetic couplers, amplifiers, processors, and the like.

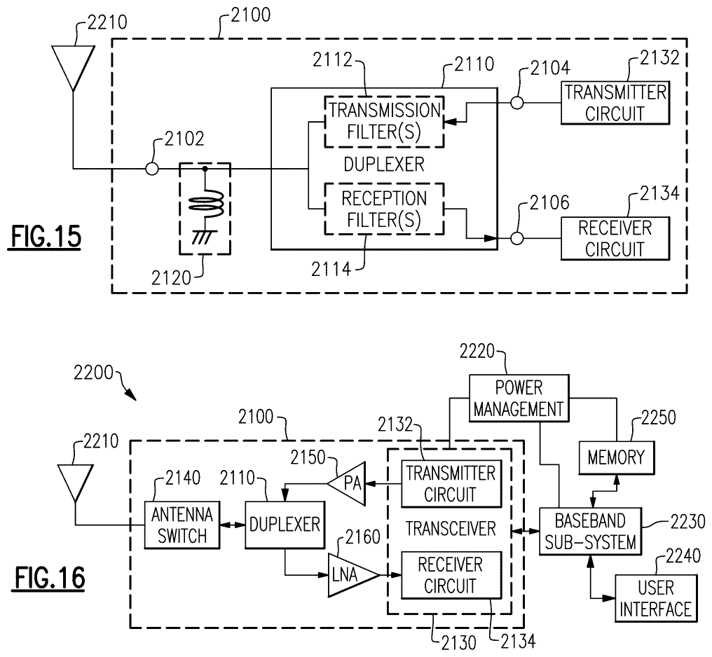

FIG. 16 is a block diagram of one example of a wireless device 2200 including the antenna duplexer 2110 shown in FIG. 15. The wireless device 2200 can be a cellular phone, smart phone, tablet, modem, communication network or any other portable or non-portable device configured for voice or data communication. The wireless device 2200 can receive and transmit signals from the antenna 2210. The wireless device includes an embodiment of a front-end module 2100 similar to that discussed above with reference to FIG. 15. The front-end module 2100 includes the duplexer 2110, as discussed above. In the example shown in FIG. 16 the front-end module 2100 further includes an antenna switch 2140, which can be configured to switch between different frequency bands or modes, such as transmit and receive modes, for example. In the example illustrated in FIG. 16, the antenna switch 2140 is positioned between the duplexer 2110 and the antenna 2210; however, in other examples the duplexer 2110 can be positioned between the antenna switch 2140 and the antenna 2210. In other examples the antenna switch 2140 and the duplexer 2110 can be integrated into a single component.

The front-end module 2100 includes a transceiver 2130 that is configured to generate signals for transmission or to process received signals. The transceiver 2130 can include the transmitter circuit 2132, which can be connected to the input node 2104 of the duplexer 2110, and the receiver circuit 2134, which can be connected to the output node 2106 of the duplexer 2110, as shown in the example of FIG. 15.

Signals generated for transmission by the transmitter circuit 2132 are received by a power amplifier (PA) module 2150, which amplifies the generated signals from the transceiver 2130. The power amplifier module 2150 can include one or more power amplifiers. The power amplifier module 2150 can be used to amplify a wide variety of RF or other frequency-band transmission signals. For example, the power amplifier module 2150 can receive an enable signal that can be used to pulse the output of the power amplifier to aid in transmitting a wireless local area network (WLAN) signal or any other suitable pulsed signal. The power amplifier module 2150 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 2150 and associated components including switches and the like can be fabricated on gallium arsenide (GaAs) substrates using, for example, high-electron mobility transistors (pHEMT) or insulated-gate bipolar transistors (BiFET), or on a silicon substrate using complementary metal-oxide semiconductor (CMOS) field effect transistors.

Still referring to FIG. 16, the front-end module 2100 may further include a low noise amplifier (LNA) module 2160, which amplifies received signals from the antenna 2210 and provides the amplified signals to the receiver circuit 2134 of the transceiver 2130.

The wireless device 2200 of FIG. 16 further includes a power management sub-system 2220 that is connected to the transceiver 2130 and manages the power for the operation of the wireless device 2200. The power management sub-system 2220 can also control the operation of a baseband sub-system 2230 and various other components of the wireless device 2200. The power management sub-system 2220 can include, or can be connected to, a battery (not shown) that supplies power for the various components of the wireless device 2200. The power management sub-system 2220 can further include one or more processors or controllers that can control the transmission of signals, for example. In one embodiment, the baseband sub-system 2230 is connected to a user interface 2240 to facilitate various input and output of voice and/or data provided to and received from the user. The baseband sub-system 2230 can also be connected to memory 2250 that is configured to store data and/or instructions to facilitate the operation of the wireless device, and/or to provide storage of information for the user.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 500 MHz to 3 GHz.

Further examples of the electronic devices that aspects of this disclosure may be implemented include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the disclosure. Accordingly, the foregoing description and drawings are by way of example only, and the scope of the disclosure should be determined from proper construction of the appended claims, and their equivalents.

What is claimed is:

1. An acoustic wave device, comprising:
a layer of carrier substrate;
a layer of dielectric material, the layer of dielectric material having a lower surface disposed against an upper surface of the layer of carrier substrate;
a layer of piezoelectric material, the layer of piezoelectric material having a lower surface disposed against an upper surface of the layer of dielectric material;
a pair of interdigital transducer electrodes disposed on an upper surface of the layer of piezoelectric material, each interdigital transducer electrode including a bus bar, and a plurality of electrode fingers extending from the bus bar to distal ends of the electrode fingers at an edge region of the interdigital transducer electrode; and
trench portions located in the upper surface of the layer of piezoelectric material, said trench portions being overlapped by the edge regions of the interdigital transducer electrodes, the electrode fingers having regions at their distal ends that have a reduced width, the reduced width regions having lengths of between about 1.1λ and 1.2λ, where λ is the wavelength of the acoustic wave to be generated.

2. The acoustic wave device of claim 1 wherein the trench portions are located in areas of the upper surface of the layer of piezoelectric material that are overlapped by the edge regions of the pair of interdigital transducer electrodes and are not covered by material of the pair of interdigital transducer electrodes.

3. The acoustic wave device of claim 1 wherein the trench portions extend discontinuously in a direction of propagation of an acoustic wave to be generated by the pair of interdigital transducer electrodes.

4. The acoustic wave device of claim 1 wherein the distal end of each of the plurality of electrode fingers has a length in a direction perpendicular to a direction of propagation of an acoustic wave to be generated by the pair of interdigital transducer electrodes of 1.2λ.

5. The acoustic wave device of claim 1 wherein the trench portions each have a width of between about 0.8λ and 1.2λ.

6. The acoustic wave device of claim 1 wherein the trench portions each have a depth relative to the upper surface of the layer of piezoelectric material of between about 0.004λ and 0.02λ.

7. The acoustic wave device of claim 1 wherein the portion of the interdigital transducer electrode with reduced width is contiguous with one or more adjacent trench portions in the layer of piezoelectric material and has a same length as the length of the one or more adjacent trench portions.

8. The acoustic wave device of claim 1 wherein a duty factor of the pair of interdigital transducer electrodes in edge regions of the pair of interdigital transducer electrodes is less than a duty factor of the pair of interdigital transducer electrodes in a central region of an active region of the pair of interdigital transducer electrodes.

9. The acoustic wave device of claim 1 wherein distal ends of the plurality of electrode fingers have a duty factor of about 0.4.

10. The acoustic wave device of claim 9 wherein the duty factor of the plurality of electrode fingers in a central region of an active region of the pair of interdigital transducer electrodes is about 0.5.

11. The acoustic wave device of claim 1 wherein the trench portions in the upper surface of the layer of piezoelectric material are also overlapped with at least part of gap regions of the pair of interdigital transducer electrodes.

12. The acoustic wave device of claim 1 wherein the trench portions each have a length that extends from the edge region of one of the pair of interdigital transducer electrodes to the bus bar of the other of the pair of interdigital transducer electrode.

13. The acoustic wave device of claim 12 wherein each of the interdigital transducer electrodes includes a second bus bar that is located within a gap region of one of the pair of interdigital transducer electrodes.

14. A radio frequency (RF) ladder filter comprising:
a set of series resonators connected in series between an input and an output of the RF ladder filter, the set of series resonators including at least one of a first type of acoustic wave device, the first type of acoustic wave device including a carrier substrate, a layer of dielectric material having a lower surface disposed against an upper surface of the carrier substrate, a layer of piezoelectric material having a lower surface disposed against an upper surface of the layer of dielectric material, a pair of interdigital transducer electrodes disposed on an upper surface of the layer of piezoelectric material, each interdigital transducer electrode including a bus bar, and a plurality of electrode fingers extending from the bus bar to distal ends of the electrode fingers at an edge region of the interdigital transducer electrode, and trench portions located in the upper surface of the layer of piezoelectric material, said trench portions being overlapped by the edge regions of the interdigital transducer electrodes, the electrode fingers having a uniform width; and
a set of parallel resonators connected in parallel between the acoustic wave devices of the set of series resonators and ground in a shunt configuration, the set of parallel resonators including at least one of a second type of acoustic wave device, the second type of acoustic wave device including a carrier substrate, a layer of dielectric material having a lower surface disposed against an upper surface of the carrier substrate, a layer of piezoelectric material having a lower surface disposed against an upper surface of the layer of dielectric material, a pair of interdigital transducer electrodes disposed on an upper surface of the layer of piezoelectric material, each interdigital transducer electrode including a bus bar, and a plurality of electrode fingers extending from the bus bar to distal ends of the electrode fingers at an edge region of the interdigital transducer electrode, and trench portions located in the upper surface of the layer of piezoelectric material, said trench portions overlapping with the edge regions of the interdigital transducer electrodes, the electrode fingers having regions at their distal ends that have a reduced width, the reduced width region having lengths of between about 1.1λ and 1.2λ, where λ is the wavelength of the acoustic wave to be generated.

15. The radio frequency ladder filter of claim 14 wherein the first type of acoustic wave device comprises trench portions each having a first width, and the second type of acoustic wave device comprises trench portions each having a second width, the second width being larger than the first width.

16. The radio frequency ladder filter of claim 15 wherein the first width is between about 0.8λ and 1.0λ.

17. The radio frequency ladder filter of claim 14 wherein the set of series resonators comprises only acoustic wave devices of the first type.

18. The radio frequency ladder filter of claim 14 wherein the set of parallel resonators comprises only acoustic wave devices of the second type.

19. The radio frequency ladder filter of claim 14 wherein the set of parallel resonators comprises a mixture of acoustic wave devices of the first and second types.

20. An electronics module comprising at least one radio frequency filter that includes at least one acoustic wave device, the at least one acoustic wave device including:
a carrier substrate;
a layer of dielectric material having a lower surface disposed against an upper surface of the layer of carrier substrate;
a layer of piezoelectric material having a lower surface disposed against an upper surface of the layer of dielectric material;
a pair of interdigital transducer electrodes disposed on an upper surface of the layer of piezoelectric material, each interdigital transducer electrode including a bus bar and a plurality of electrode fingers extending from the bus bar to distal ends of the electrode fingers at an edge region of the interdigital transducer electrode; and
trench portions located in the upper surface of the layer of piezoelectric material, said trench portions being overlapped by the edge regions of the interdigital transducer electrodes, the electrode fingers having regions at their distal ends that have a reduced width, the reduced width regions having a length of between about 1.1λ and 1.2λ, where λ is the wavelength of the acoustic wave to be generated.
